(19) United States
(12) Patent Application Publication
(10) Pub. No.: US 2008/0042636 A1
(43) Pub. Date: Feb. 21, 2008

(54) SYSTEM AND METHOD FOR CURRENT SENSING

(75) Inventors: GLEN PETER KOSTE, NISKAYUNA, NY (US); YUN (NMN) LI, NISKAYUNA, NY (US); JOHN STANLEY GLASER, NISKAYUNA, NY (US); MICHAEL ANDREW DE ROOIJ, SCHENECTADY, NY (US); LJUBISA DRAGOLJUB STEVANOVIC, CLIFTON PARK, NY (US); RICHARD ALFRED BEAUPRE, PITTSFIELD, MA (US); HUA (NMN) XIA, ALTAMONT, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: GENERAL ELECTRIC COMPANY, SCHENECTADY, NY (US)

(21) Appl. No.: 11/465,474

(22) Filed: Aug. 18, 2006

(51) Int. Cl. G01R 31/00

(52) U.S. Cl. 324/96

(57) ABSTRACT

A current sensing system for estimating current in substantially parallel planar conductors. The system includes a magnetostrictive optical sensor including an optical sensing element coupled to a magnetostrictive element and disposed between substantially parallel planar conductors, wherein the magnetostrictive element is configured to cause a strain in the optical sensing element in the presence of a magnetic field between the substantially parallel planar conductors, and wherein the optical sensing element is configured to receive an optical interrogation signal and provide a wavelength modulated data signal indicative of magnitude of the current flowing through the conductors.

### BACKGROUND

The invention relates generally to current sensing systems and more particularly to optical current sensing systems.

Known current measurement techniques include techniques where current is measured by passing it through a very low resistance shunt resistor of known value and the voltage across this shunt resistor is measured. This approach has the advantage of direct current (DC) to 10 mega hertz (MHz) measurement capability, but one drawback is dissipation of power in the shunt resistor leading to generation of heat which in turn may cause inaccuracy in the measurement as the resistance value of the shunt resistor may vary with temperature. A variation on the shunt resistor technique includes the use of a current transformer. This isolates the current sensor from the circuit and dissipates less power. However, the current transformer cannot be used to measure DC currents because DC currents cannot pass through the transformer.

Another known method for sensing current uses a Rowgowski Coil. This technique cannot be used to measure DC currents and has lower bandwidth capability than the current transformer technique. A Hall effect sensor with a magnetic field concentrator and a feedback circuit to cancel the magnetic field in the Hall effect sensor can also be used to measure current. But the technique requires a large amount of volume and has limited bandwidth, typically below 100 kilo hertz (kHz).

Power electronic converters require accurate and timely information about the currents flowing through specific components in the system. Most power electronic converter applications have a need for current sensors which are fully isolated from the high voltages in the power circuit and which avoid the drawbacks of currently known current sensing techniques.

### BRIEF DESCRIPTION

One embodiment of the present invention is a current sensing system for estimating current in substantially parallel planar conductors. The system includes a magnetostrictive optical sensor including an optical sensing element coupled to a magnetostrictive element and disposed between substantially parallel planar conductors, wherein the magnetostrictive element is configured to cause a strain in the optical sensing element in the presence of a magnetic field between the substantially parallel planar conductors, and wherein the optical sensing element is configured to receive an optical interrogation signal and provide a wavelength modulated data signal indicative of magnitude of the current flowing through the conductors.

Another embodiment of the present invention is a system for measuring current in a conduction line. The system includes an in-line current sensor module disposed along the conduction line, wherein the in-line current sensor module includes a connector including two substantially parallel planar portions and a magnetostrictive optical sensor disposed between the substantially parallel planar portions of the connector, wherein the magnetostrictive optical sensor comprises an optical sensing element coupled to a magnetostrictive element.

Another embodiment of the present invention is a power electronic assembly. The assembly includes at least one power electronic device, at least one power module including two substantially parallel planar conductors electrically coupled to and supplying power to the at least one power electronic device and a magnetostrictive optical current sensor disposed between the substantially parallel planar conductors, wherein the magnetostrictive optical current sensor includes an optical sensing element coupled to a magnetostrictive element, wherein the magnetostrictive element is configured to cause a strain in the optical sensing element in the presence of a magnetic field between the substantially parallel planar conductors, and wherein the optical sensing element is configured to receive an optical interrogation signal and provide a wavelength modulated data signal indicative of magnitude of the current flowing through the conductors.

Another embodiment of the present invention is a method for estimating current in a power electronic device using a magnetostrictive optical sensor disposed between substantially parallel planar conductors electrically coupled to the power electronic device. The method includes electrically powering the power electronic device by sending current through the substantially parallel conductors, wherein the current generates a magnetic field between the conductors and the magnetic field produces a strain in the magnetostrictive optical sensor, interrogating the magnetostrictive optical sensor using a multi-frequency interrogation signal, wherein the magnetostrictive optical sensor modulates the multi-frequency interrogation signal to provide a wavelength modulated signal indicative of the current, detecting the wavelength modulated signal; and estimating a value of the current.

### DRAWINGS

These and other features, aspects, and advantages of the present invention will become better understood when the following detailed description is read with reference to the accompanying drawings in which like characters represent like parts throughout the drawings, wherein:

FIG. 1 is a schematic view of parallel conductors conducting current in opposite directions generating a uniform magnetic field B between the conductors in accordance with one embodiment of the present invention.

FIG. 2 is a schematic representation of a magnetostrictive optical sensor in one embodiment of the present invention.

FIG. 3 is a schematic representation of a magnetostrictive optical sensor in one embodiment of the present invention.

FIG. 4 is a schematic representation of a system for measuring current in a conduction line in one embodiment of the present invention.

FIG. 5 is a schematic representation of a system for measuring current in a conduction line including an electromagnetic interference shield in one embodiment of the present invention.

FIG. 6 is a schematic view of a power electronic assembly in accordance with another embodiment of the present invention.

FIG. 7 is a sectional view of a power electronic assembly shown in FIG. 6 in one embodiment of the present invention.

FIG. 8 is a schematic view of substantially parallel planar conductors separated by a dielectric conducting current in opposite directions generating a uniform magnetic field B between the conductors in accordance with one embodiment of the present invention.

FIG. 9 is a graphical representation of magnetic field B versus distance along the width w of the substantially parallel planar conductors conducting a DC current in opposite directions in one embodiment of the present invention.

FIG. 10 is a graphical representation of magnetic field B versus distance along the separation d between the substantially parallel planar conductors conducting a DC current in opposite directions in one embodiment of the present invention.

FIG. 11 is a graphical representation of magnetic field B versus distance along the width w of the substantially parallel planar conductors conducting a current of 1 MHz AC current in opposite directions in one embodiment of the present invention

FIG. 12 is a graphical representation of magnetic field B versus distance along the separation d between the substantially parallel planar conductors conducting a current of 1 MHz AC current in opposite directions in one embodiment of the present invention

FIG. 13 is a graphical representation of grating reflection wavelength shift versus microstrain induced for an optical grating magnetostrictive sensor in one embodiment of the present invention.

### DETAILED DESCRIPTION

Power electronic package design is moving towards low inductance designs that result in uniform magnetic fields between the conductors, which are directly correlated to the current. Embodiments of the present invention relate to systems and methods for current sensing between parallel conductors conducting current I in opposite directions using a magnetostrictive optical sensor. As used herein, the term “current” can refer to either alternating current (AC) or direct current (DC). Magnetostriction is a mechanism by which individual magnetic domains in a material are reoriented under the influence of an applied external magnetic field leading to a dimensional change in the material. The amount of dimensional change produced in the material is dependent on the applied magnetic field and various properties of the material including the magnetostrictive constant. In one embodiment of the present invention, this dimensional change, which can be correlated to the applied magnetic field, is measured by coupling the magnetostrictive material to an optical sensing element which is configured to wavelength modulate an interrogation signal corresponding to the dimensional change in the magnetostrictive material.

As used herein, the term “optical” refers to electromagnetic radiation in the infrared, visible and ultra violet frequency region of the electromagnetic spectrum.

As used herein, the term “optical filter” refers to an optical element or device, which preferentially reflects or transmits light at a particular wavelength.

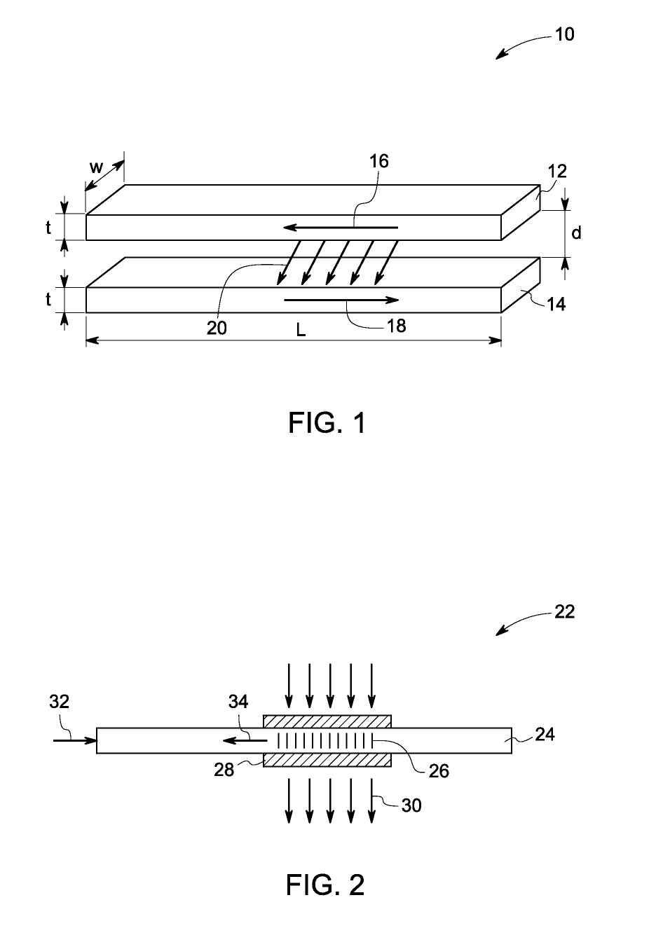

Although the applicants do not wish to be bound by any particular theory, the following analysis has been presented to illustrate how the magnitude of the magnetic field developed between parallel planar conductors can be calculated for a given set of parameters. FIG. 1 illustrates parallel planar conductors 10 conducting a current I. In one embodiment, the two conductors 12 and 14 conduct direct current (DC) I along opposite directions indicated by arrows 16 and 18. When a current I flows through a planar conductor, the current flow can be considered as a moving sheet of charge. For parallel conductors with width w substantially larger than the separation d, assuming a charge density of σ and a current flow velocity v, the magnetic field B 20 generated between the parallel planar conductors is normal to the direction of current flow and parallel to the plane of the conductors and the magnitude of the field is given by

$$B = 2 \times \frac{v {σμ}_{o}}{2} \qquad ( 1 )$$

where μₒ is the permeability of free space. The magnetic field due to each of the two planar conductors is given by vσμ₀/2. If w is the width of the planar conductors, then current I can be written as

I=vσw. (2)

### Therefore,

$$v σ = \frac{I}{w} . \qquad ( 3 )$$

### Substituting for vσ in equation 2, gives a magnetic field B of magnitude

$$B = \frac{I {μ}_{o}}{w} \qquad ( 4 )$$

Therefore, the magnetic field between parallel conductors with width w substantially larger than the separation d conducting a DC current I in opposite directions, is dependent on the current I, and the width w of the conductors, and is independent of the separation between the conductors. For a DC current, the magnetic field B is linearly proportional to the current.

In another embodiment, the two conductors 12 and 14 conduct alternating current (AC). When an alternating current with magnitude Iₐₘₚ and frequency f flows through parallel conductors with width w, separated by an insulator with thickness tᵢₙₛ equal to the separation d, a magnetic field B is generated between the parallel planar conductors in a direction normal to the direction of current flow and parallel to the plane of the conductors. Using the Biot-Savart law, the magnitude of the field at the center between the two conductors is given by

$$B = \frac{{I}_{amp} {μ}_{o}}{\sqrt{{w}^{2} + {d}_{eff}^{2}}} , \qquad ( 5 )$$

where d_{eff} is given by

d_{eff}=tᵢₙₛ+2δ, (6)

where δ is the skin depth of the current in the conductor given by

$$δ = \frac{1}{\sqrt{f {πμ}_{o} {μ}_{r} {σ}_{c}}} , \qquad ( 7 )$$

where f is the frequency of alternating current, μ₀ is the permeability of free space, μᵣ is the relative permeability of the conductor, and σ_{c} is the conductivity of the conductors. Therefore the magnitude of the B field is a linear function of the current amplitude in the conductors with a predictable non-linear relationship with respect to the frequency of the current.

FIG. 2 illustrates a magnetostrictive optical sensor 22 in one embodiment of the present invention. The magnetostrictive sensor 22 includes a fiber 24 with an in-fiber grating 26. A magnetostrictive element 28 is coupled to the fiber 24. The magnetostrictive element in the presence of an external magnetic field 30 is configured to cause a change in the in-fiber grating spacing. When a multi-frequency input optical signal 32 is coupled into the fiber 24, at the grating a reflection signal 34 at a frequency characteristic of the grating spacing is generated. As the magnetic field varies, the frequency of the reflected signal also varies as a consequence. In a non-limiting example, the magnetostrictive element is bonded, or glued to the fiber at the in-fiber grating. In another example, the magnetostrictive element forms an encasing around the in-fiber grating. The magnetostrictive element includes magnetostrictive material such as but not limited to Terfenol-D® alloy of the formula Tb_{0.3}Dy_{0.7}Fe_{1.9}), Galfenol (alloy of Fe_{81.6}Ga_{18.4}). Metglass (alloy of Fe₄₀Ni₄₀P₁₄B₆), NiTi, CuZn, NiMnGa, DyFe₂ and alloys of cobalt iron nickel, and alloys of rare earth elements such as terbium and dysprosium. In one embodiment, the magnetostrictive material has a magnetostrictive constant greater than 1000 ppm. In one embodiment, the fiber Bragg grating is a short-period Bragg grating with a grating period less than 1 micrometer. In some embodiments, the optical sensing element and the magnetostrictive element form an integrated unit.

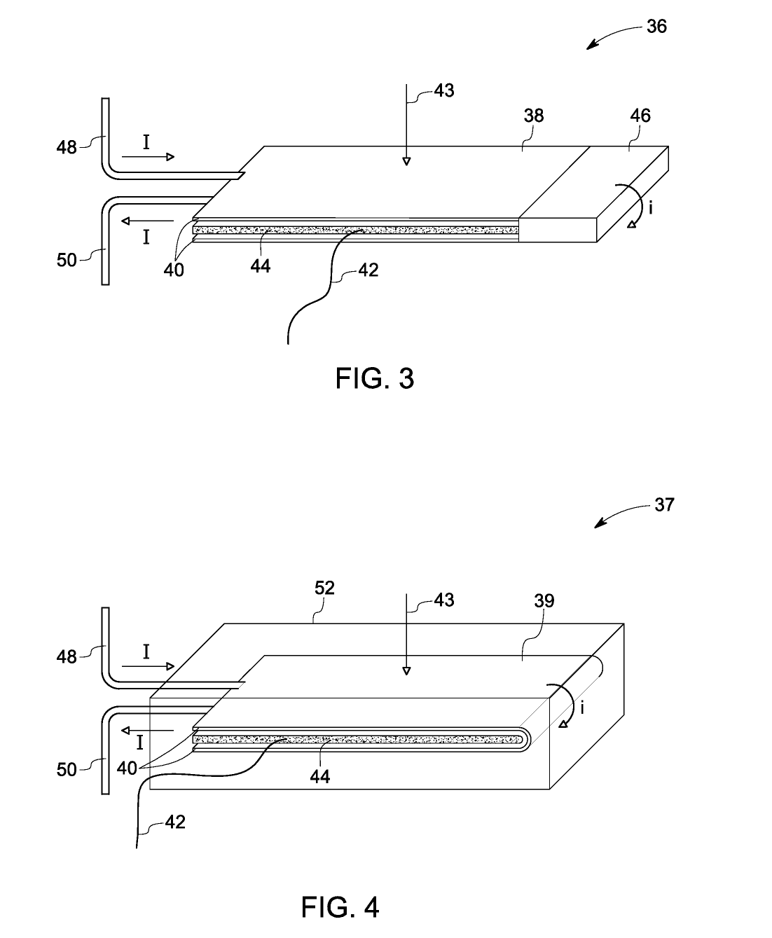

In one embodiment of the present invention is a system for measuring current along a conduction line as illustrated in FIG. 3. The system includes an in-line current sensor module 36 including a connector 38, and is connected in series with the conduction line. The connector includes two planar portions 40 substantially parallel to each other, referred to henceforth as substantially parallel planar portions, and a magnetostrictive optical sensor 42 disposed between the substantially parallel planar portions 40 of the connector in the region of substantially uniform magnetic field 43. As used herein and throughout the following description, the term “substantially parallel planar portions” refers to planar portions disposed substantially parallel with respect to each other in a manner so as to produce on current conduction, a magnetic field across an active sensing region of the magnetostrictive optical sensor disposed between the substantially parallel portions with a variation of less than 15% as compared to a magnetic field produced by planar portions ideally parallel conducting the same current.

In one embodiment, the substantially planar portions produce on current conduction a magnetic field across an active sensing region of the sensor with a variation of less than 10% as compared to a magnetic field produced by planar portions ideally parallel conducting the same current. In a further embodiment, the substantially planar portions produce on current conduction a magnetic field across an active sensing region of the sensor with a variation of less than 5% as compared to a magnetic field produced by planar portions ideally parallel conducting the same current.

The magnetostrictive optical sensor 42 includes an optical sensing element coupled to a magnetostrictive element. In one embodiment, the magnetostrictive optical sensor 42 is embedded in a dielectric 44 disposed between the substantially parallel planar portions of the connector. The current I flows along the conduction line segment 48 into the in-line current sensor module 36 and out of the current sensor module 36 through the conduction line segment 50.

In some embodiments, the connector is a multi-component structure including two substantially parallel planar portions 42 connected in series using a conductor segment 46 as shown in FIG. 3. In other embodiments, the system for measuring current in a conduction line includes an in-line current sensor module 37 including a connector 39 having a unitary structure bent at one end to bring the planar portions 40 of the connector to be substantially parallel as illustrated in FIG. 4. In one embodiment, the magnetostrictive optical sensor 42 is embedded in a dielectric 44 disposed between the substantially planar portions 40 of the connector in the region of substantially uniform magnetic field 43. The system may further include an electromagnetic interference shield (EMI shield) 52 surrounding the current sensor, as illustrated in FIG. 4, to prevent external electromagnetic fields from influencing the magnetostrictive optical sensor 42.

The use of such in-line current sensor modules to measure current in a conduction line is expected to be advantageous in many systems including industrial and aerospace power management and distribution systems.

In a further embodiment of the present invention, the system for measuring current includes an interrogation module including a multi-frequency optical source configured to generate an optical interrogation signal and further configured to transmit the signal to the optical sensing element in the magnetostrictive optical sensor. As used herein, the term “multi-frequency optical source” refers to an optical source emitting light at a plurality of wavelengths such as but not limited to a broadband optical source, a Fabry-Perot laser, an external cavity laser, or an optical device including a plurality of light sources emitting at a plurality of wavelengths.

The optical sensing element reflects or transmits light at a wavelength corresponding to the value of the current and generates a sensor data signal. The interrogation module further includes a photodetector configured to detect the sensor data signal. In one embodiment, a reference sensor is used to generate the reference signal from the optical interrogation signal. The photodetector generates an electrical difference frequency signal corresponding to a wavelength difference between the reference signal and the optical sensor data signal. In one embodiment, the electrical frequency detection occurs through the use of a series of electrical filters, power detectors, and mixers to generate a binary representation of the frequency. In another embodiment, frequency discriminators are used to measure the frequency of the electrical difference frequency signal. As will be appreciated by one skilled in the art, many techniques are known for measuring the frequency of such signals. While a few representative examples of frequency measurement modules have been presented here, the scope of the invention is not limited to these specifically described examples. All present and future alternatives for measuring the frequency of such signals fall within the scope of the invention. A reference signal is also advantageous in canceling out the changes in the characteristic frequencies due to factors such as a temperature change. General principles of such optical interrogation and frequency measurement can be more clearly understood by referring to co-pending Application having Ser. No. 11/277,294, filed on Mar. 23, 2006, which is incorporated herein by reference in its entirety.

Suitable examples of multi-frequency optical sources include broadband optical sources, which emit light over a range of frequencies and Fabry-Perot and external-cavity lasers, which emit a comb of wavelengths spaced evenly apart as determined by the laser cavity length.

In one embodiment, the optical sensing element filters light at a particular wavelength. Suitable examples of optical sensing elements for use in embodiments in the present invention include tunable optical filters, which exhibit variations in their characteristic frequency at which they reflect or transmit, under the influence of an applied stimuli. One non-limiting example of an optical filter is a Bragg grating, specifically a fiber Bragg grating. Typically, a fiber Bragg grating consists of refractive index modulation along a portion of a fiber with a specified period. Fiber Bragg gratings are based on the principle of Bragg reflection. When light propagates through periodically alternating regions of higher and lower refractive index, the light is partially reflected at each interface between those regions. A series of evenly spaced regions results in significant reflections at a single frequency while all other frequencies are transmitted with little attenuation. When a Bragg grating is used, the grating thus acts as a notch filter, which reflects light of a certain wavelength. Since the frequency, which is reflected, is dependent on the grating period, a small change in the length of the fiber can be detected as a frequency shift.

One alternative to fiber gratings, for example, is a Fabry-Perot in-fiber sensor, which reflects light strongly at resonant wavelengths. The pattern of reflected light is affected by the length of the Fabry-Perot cavity. Other non-limiting examples of optical sensing elements include filters such as but not limited to optical microresonators, which typically filter light at a particular characteristic frequency in response to external stimuli, in this case, a magnetic field. The change in the characteristic frequency typically results due to a change in the resonator length.

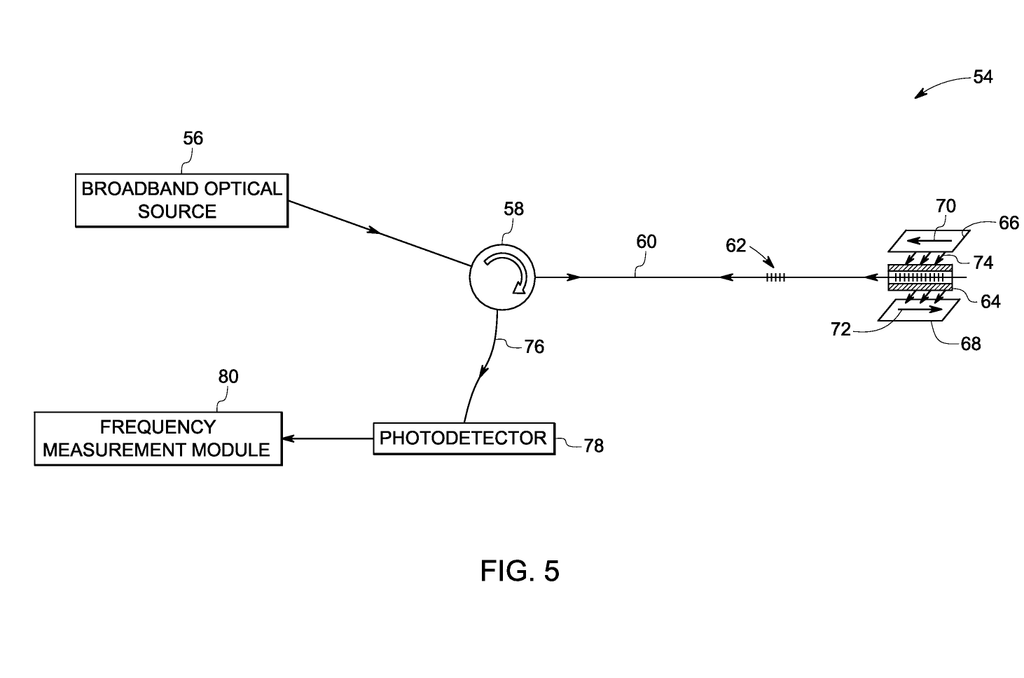

In the illustrated embodiment shown in FIG. 5, an optical interrogation module 54 includes a broadband optical source 56, light from which is coupled through an optical circulator 58 to a fiber 60 through to an in-fiber reference sensor 62 (such as a Bragg grating), and an in-fiber magnetostrictive optical sensor 64 (such as a Bragg grating). The in-fiber reference sensor 62 and magnetostrictive optical sensor 64 have characteristic reflection frequencies. The magnetostrictive optical sensor 64 is positioned between substantially parallel planar conductors 66, 68, conducting a current I along the directions indicated by the arrows 70 and 72 respectively. Due to the current I flowing in the conductors a magnetic field B 74 is established between the conductors. The magnetostrictive optical sensor 64 is configured to respond to variations in the magnetic field in time. The characteristic reflection frequency of the magnetostrictive optical sensor varies as a result of variations in the magnetic field.

A reference wavelength component ωᵣ of the incident broadband light is reflected by the reference sensor to form the reference signal, and a data sensor wavelength component ωₒ of the incident broadband light is reflected by the magnetostrictive optical sensor to form the sensor data signal. The signals are carried back along the same fiber 60 to the optical signal-directing element 58, which separates the forward and backward propagating signals. Suitable examples of optical signal directing elements include optical circulators and directional couplers. The reference signal and the sensor data signal are coupled into a photodetector 78 through a fiber 76. Since a photodetector is a square law detector, the two optical signals mix and form sum and difference signals in the electrical domain. The electrical frequency of the difference signal directly correlates to the difference in the optical wavelengths of the reference and sensor data signals. The electrical frequency of the difference signal is detected by an electrical frequency measurement module 80. The above described embodiments were primarily described in terms of a single magnetostrictive optical sensor, reference sensor, an optical source, a photodetector and a frequency measurement module for purposes of example, however, each system may include one or more of such elements and “a” as used herein is intended to mean “at least one.”

In another embodiment of the present invention is a power electronic assembly. The assembly includes at least one power electronic device, and at least one power module including two substantially parallel planar conductors electrically coupled to and supplying power to the at least one power electronic device and a sensor disposed between the substantially parallel conductors. As used herein, the term “substantially parallel planar conductors” refers to conductors each having at least a planar portion disposed substantially parallel with respect to each other to form substantially parallel planar portions. As used herein, the term “disposed between substantially parallel conductors” refers to disposing between the planar portions of the conductors.

It is not critical that the substantially parallel planar conductors remain substantially parallel throughout their entire path, but it is expected to be useful for them to remain substantially parallel across the entire sensor and extending on either side of the sensor by at least the sensor's width. It is also expected that accuracy of the sensed parameter will be increased as the sensor size is decreased in comparison to the electrical conductor width.

In one embodiment, the magnetic field generated by the substantially parallel planar conductors is uniform to within 15% for at least the middle third of the length of the substantially parallel planar conductors. In a further embodiment, the magnetic field generated by the substantially parallel planar conductors is uniform to within 10% for at least the middle third of the length of the parallel planar conductors. In a still further embodiment, the magnetic field generated by the substantially parallel planar conductors is uniform to within 5% for at least the middle third of the length of the parallel planar conductors.

The power module further includes a magnetostrictive optical current sensor including a magnetostrictive element coupled to an optical sensing element disposed between the substantially parallel planar conductors. The magnetostrictive element is configured to cause a strain in the optical sensing element in the presence of a magnetic field created by current flowing through the substantially parallel planar conductors in opposite directions, and the optical sensing element is configured to receive an optical interrogation signal and provide a wavelength modulated signal indicative of the magnitude of the magnetic field. In one embodiment the optical sensing element is a fiber Bragg grating.

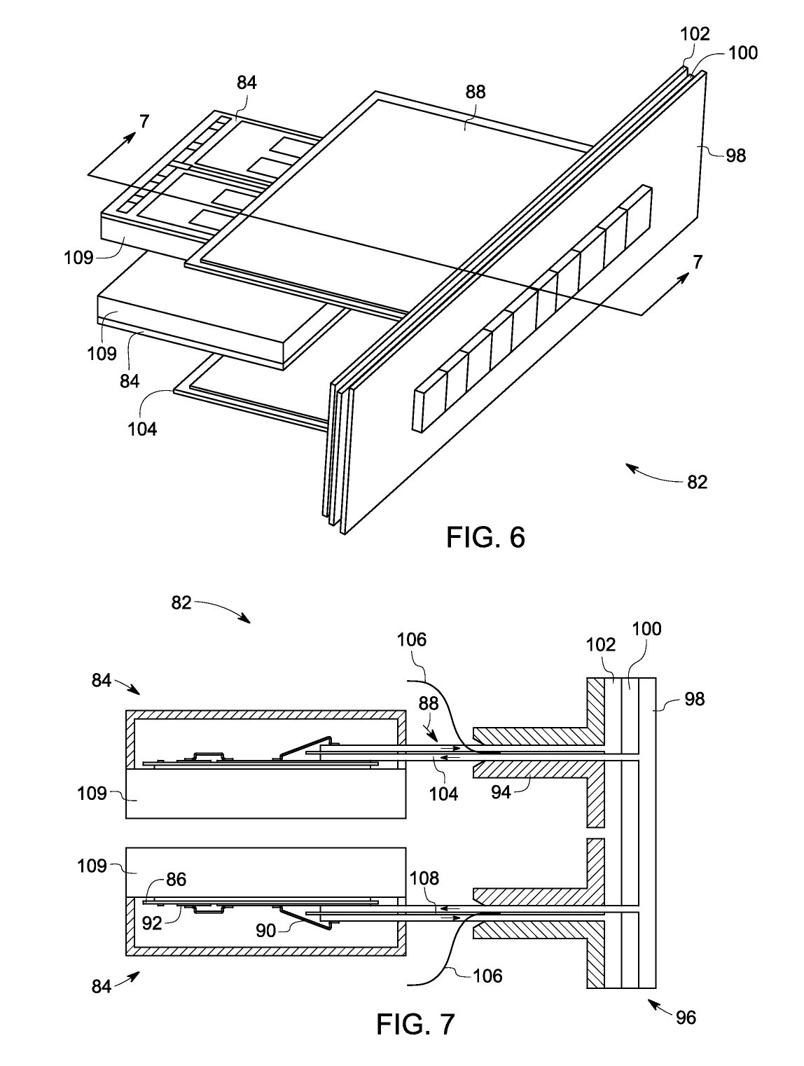

In the embodiment shown in FIGS. 6 and 7, a power electronic assembly 82 includes two power modules 84. Each of the power modules 84 includes a substrate 86, an edge card connector 88, and electrical connections 90. The power modules provide interconnection between the power source (backplane 96) to the power devices 92. Exemplary power devices include transistors, Insulated Gate Bipolar Transistors (IGBT), Metal Oxide Semiconductor Field Effect Transistors (MOSFET), and diodes. Those skilled in the art will recognize that these are examples of power devices and that the invention is by no means limited to these examples. All present and future power devices fall within the scope of the invention.

The power electronic assembly 82 further includes a number of receptacles 45 configured to receive respective edge card connectors 88. In certain embodiments, the receptacles 94 have current ratings of at least one hundred Amperes (100 A). In some embodiments the receptacles have current ratings of at least four hundred Amperes (400 A). The power module 84 further includes a back plane 96, which includes a positive direct current DC bus layer 98, an output layer 100 and a negative DC bus layer 102, as illustrated in FIGS. 6 and 7, for example. The substantially parallel planar conductors 104 of the edge card connector 88, conducting the current to the device 92 are separated by a dielectric element 108. In one embodiment, the dielectric material is a paramagnetic material. In another embodiment, the dielectric material is a diamagnetic material of known relative permeability. A magnetostrictive optical sensor 106 is embedded in the dielectric element 108 between the conductors 104. On passage of current through the conductors the magnetostrictive optical sensor is subjected to a substantially uniform magnetic field.

An optical interrogation module including a multi-frequency source may be used to probe the magnetostrictive optical sensors to determine the reflection wavelength from the optical sensing element and accordingly the current passing through the conductors 104. As shown in FIGS. 6 and 7, in one embodiment, the power modules 84 are arranged such that their respective base plates 109 face each other.

Without further elaboration, it is believed that one skilled in the art can, using the description herein, utilize the present invention to its fullest extent. The following examples are included to provide additional guidance to those skilled in the art in practicing the claimed invention. The examples provided are merely representative of the work that contributes to the teaching of the present application. Accordingly, these examples are not intended to limit the invention, as defined in the appended claims, in any manner.

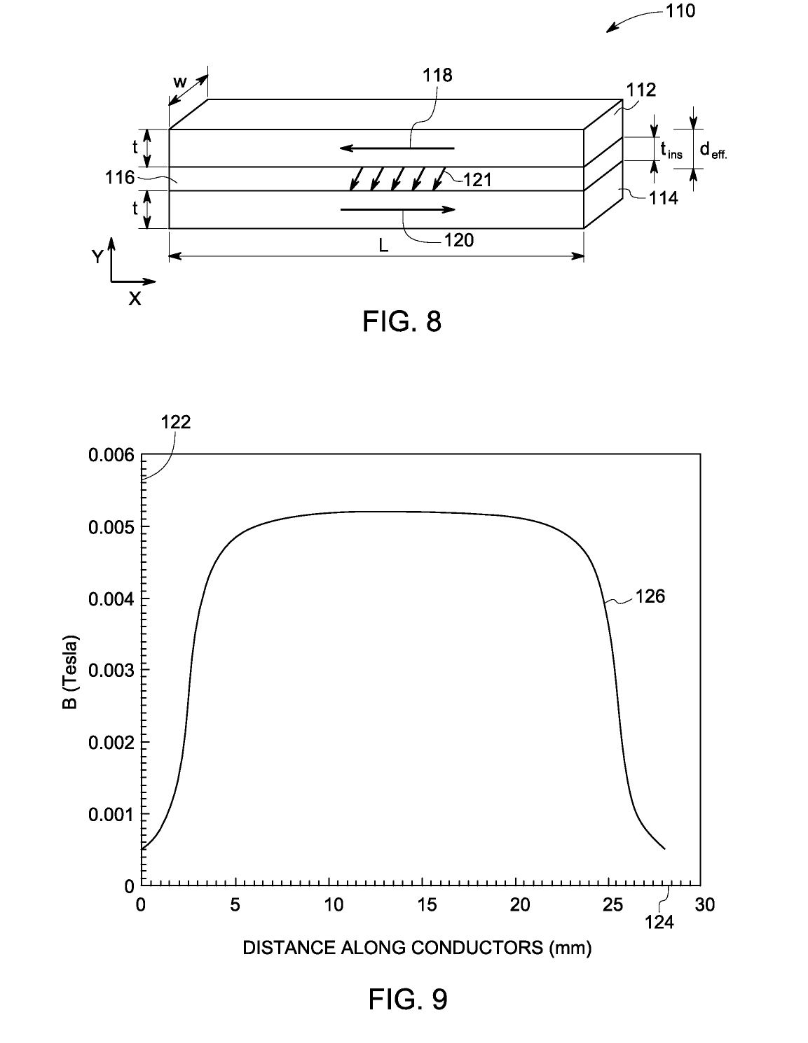

FIG. 8 illustrates substantially parallel planar conductors 110. The two conductors 112 and 114 have a length, L equal to 3.82 cm, width w equal to 2.26 cm, a thickness d equal to 0.147 cm and separated by a dielectric material 116, KAPTON® polyimide, of thickness t equal to 0.0254 cm. KAPTON® polyimide exhibits a relative permeability value of 1. When the conductors conduct a current I along directions 118 and 120, a magnetic field B 121 is generated between the conductors.

### EXAMPLE 1

A 100 A DC current or low frequency AC is passed through the substantially parallel planar conductors in opposite directions.

FIG. 9 is a graphical representation of the variation in magnetic field B with distance along the width w of the substantially parallel planar conductors. The Y-axis 122 represents the magnitude of the magnetic field and the X-axis 124 represents the distance along the width of the conductors on the center line between the parallel conductors. The line plot 126 shows a magnetic field profile, which is more flat in the central portions of the center line along the width of the conductor (about 5.2 mT) compared to the portions towards the edges of the center line along the width of the conductor.

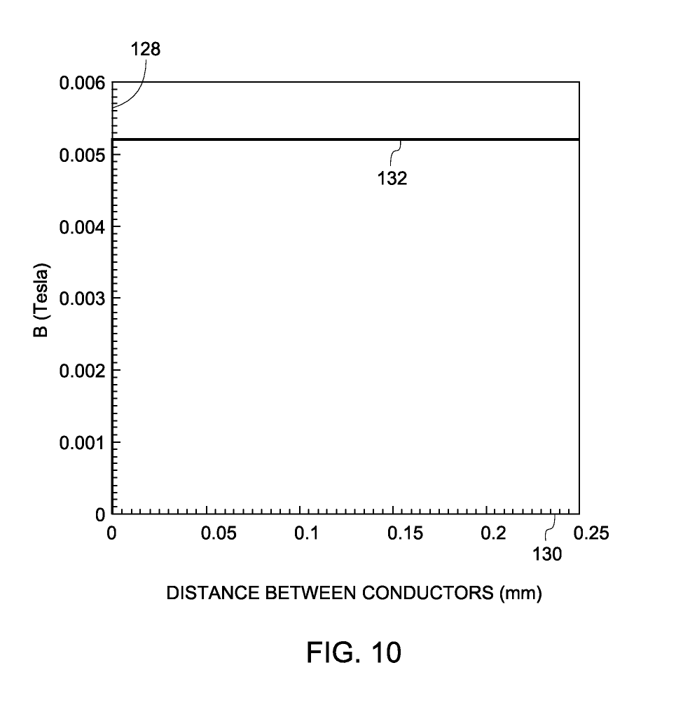

FIG. 10 is a graphical representation of the variation in magnetic field B 128 with distance 130 along the separation d between the substantially parallel planar conductors. The Y-axis 132 represents the magnitude of the magnetic field and the X-axis 134 represents the distance between the conductors. The line plot 104 illustrates the uniform magnetic field of about 5.2 mT that is produced between the conductors.

### EXAMPLE 2

A 100 A high frequency AC current is passed through the substantially parallel planar conductors in opposite directions.

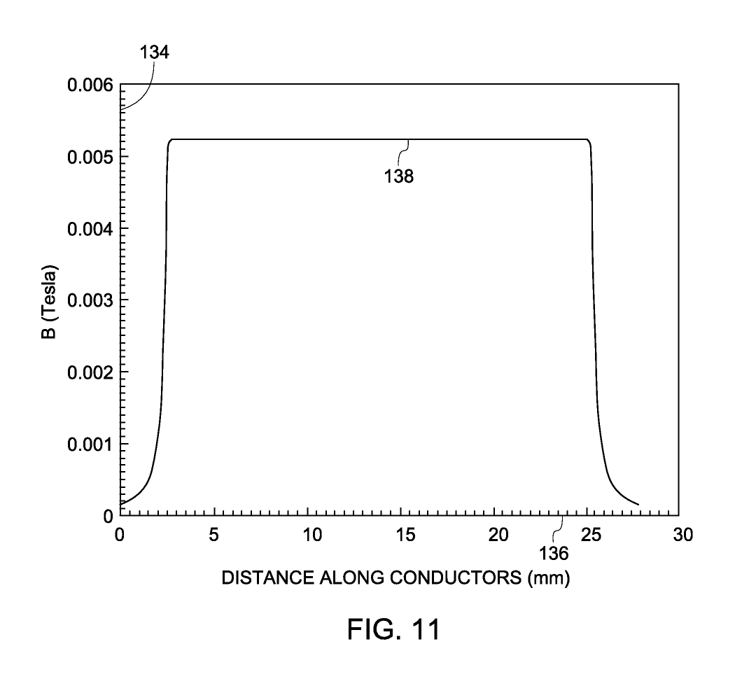

FIG. 11 is a graphical representation of the variation in magnetic field B with distance along the width w of the substantially parallel planar conductors. The Y-axis 134 represents the magnitude of the magnetic field and the X-axis 136 represents the distance along the width of the conductors on the center line between the parallel conductors. The line plot 138 shows a near uniform magnetic field of about 5.25 mT through a majority of the length of the conductors with the magnetic field value abruptly dropping in magnitude close to the edges of the conductors.

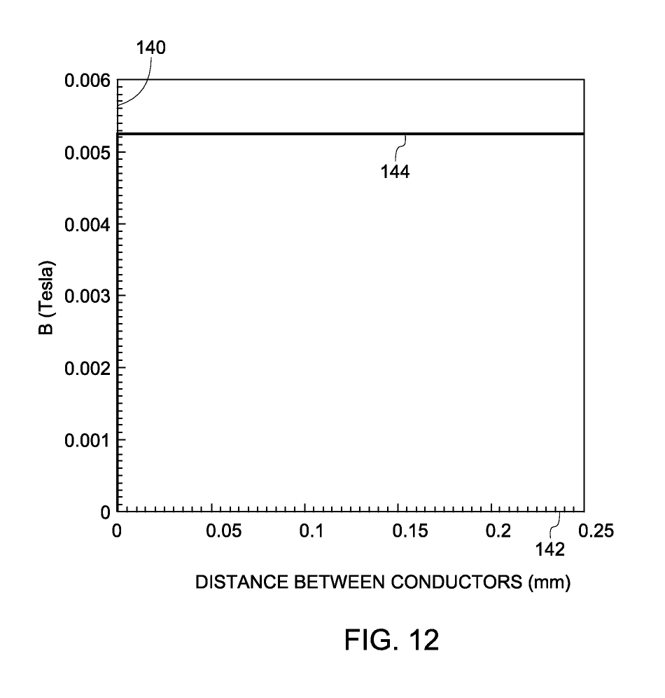

FIG. 12 is a graphical representation of variation in magnetic field B with distance along the separation d between the substantially parallel planar conductors. The Y-axis 140 represents the magnitude of the magnetic field and the X-axis 142 represents the distance between the conductors. The line plot 144 illustrates a uniform magnetic field of about 5.25 mT produced between the conductors.

### EXAMPLE 3

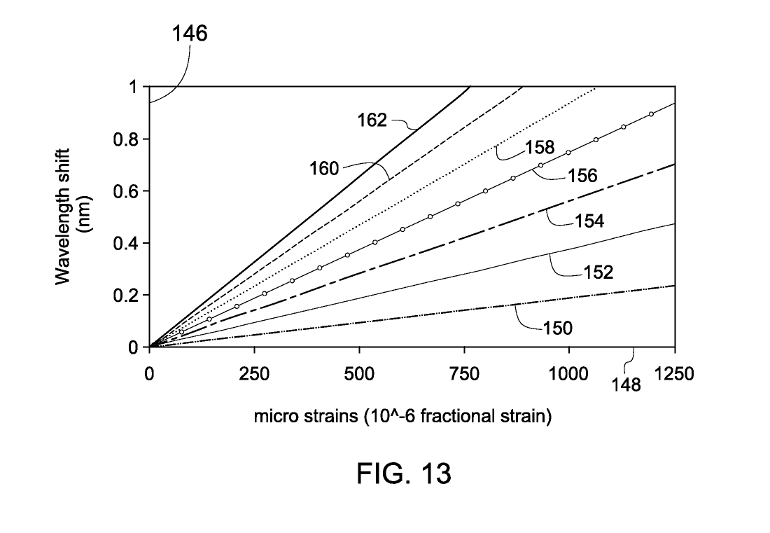

The variation in fiber grating reflection wavelength shift with microstrain induced for an optical grating magnetostrictive sensor for various interrogation signal center frequencies was calculated. In FIG. 13, the Y-axis 146 represents the grating reflection wavelength shift and the X-axis 148 represents the microstrain. The relaxed grating period was 517.2414 nm. The line plots 150, 152, 154, 156, 158, 160, and 162 illustrate the variation in grating reflection wavelength shift as a function of strain for center wavelengths 250 nm, 500 nm, 750 nm, 1000 nm, 1250 nm, 1500 nm, and 1750 nm respectively.

The magnetic field B generated in the dielectric in this example is about 52 μT/A. To measure a current in a range from 0 A to about 200 A, a magnetic field B from 0 to 0.01 Tesla needs to be typically measured. For example, a difference frequency interrogation module as shown in FIG. 5 is used to measure the wavelength shift. In one example, a wavelength shift of 0.4 nm is required to generate a difference frequency signal in the 0 to 50 GHz range. Assuming a 1500 nm nominal grating wavelength, the magnetic field B is then required to produce a strain in the grating in the range of 0 to 350 microstrain. With a strain to wavelength sensitivity of 1.2 pm per microstrain, a wavelength shift up to 360 pm can be obtained. The magnetostrictive material in the magnetostrictive element is chosen to produce the required strain in the grating.

The previously described embodiments of the present invention have many advantages, including providing current sensors isolated from high voltages, which provide more accurate and timely information about currents flowing through specific components in electronic device assemblies. The embodiments of the present invention are especially suited for power electronic packages with low inductance designs that result in uniform magnetic fields between the conductors correlated directly to the current.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A current sensing system for estimating current in substantially parallel planar conductors, the system comprising:
a magnetostrictive optical sensor, wherein the magnetostrictive optical sensor comprises an optical sensing element coupled to a magnetostrictive element and disposed between substantially parallel planar conductors;
wherein the magnetostrictive element is configured to cause a strain in the optical sensing element in the presence of a magnetic field between the substantially parallel planar conductors,
wherein the optical sensing element is configured to receive an optical interrogation signal and provide a wavelength modulated data signal indicative of magnitude of the current flowing through the conductors.

2. The system of claim 1, wherein the optical sensing element is configured to filter light at a wavelength corresponding to the magnetic field value.

3. The system of claim 2, wherein the optical sensing element is a reflection filter or a transmission filter.

4. The system of claim 3, wherein the optical sensing element comprises at least one sensing element selected from the group consisting of fiber Bragg gratings, fiber Fabry Perot cavities, optical microresonators, thin film filters, acousto-optic filters and combinations thereof.

5. The system of claim 1, further comprising a reference sensing element to generate a reference signal.

6. The system of claim 5, wherein the optical sensing element and the reference sensing element comprise fiber Bragg gratings on a single fiber.

7. The system of claim 1, wherein the magnetostrictive element comprises at least one material selected from the group consisting of Terfenol-D, Galfenol, Metglass, NiTi, CuZn, NiMnGa, DyFe₂ and alloys of cobalt, iron, nickel, alloys of rare earth elements, and combinations thereof.

8. The system of claim 1, wherein the magnetostrictive element forms an encasing around the optical sensing element.

9. The system of claim 1, wherein the optical interrogation signal comprises a multifrequency signal.

10. A system for measuring current in a conduction line comprising:
an in-line current sensor module disposed along the conduction line, wherein the current sensor comprises:
a connector comprising two substantially parallel planar portions; and
a magnetostrictive optical sensor disposed between the substantially parallel planar portions of the connector, wherein the magnetostrictive optical sensor comprises an optical sensing element coupled to a magnetostrictive element.

11. The system of claim 10, wherein the magnetostrictive optical sensor is embedded in a dielectric disposed between the substantially parallel portions of the connector.

12. The system of claim 10, wherein the system further comprising an EMI shield to shield the current sensor modulefrom extermal electromagnetic interference.

13. The system of claim 10, further comprising an optical interrogation module.

14. A power electronic assembly comprising:
at least one power electronic device;
at least one power module comprising two substantially parallel planar conductors electrically coupled to and supplying power to the at least one power electronic device; and
a magnetostrictive optical current sensor disposed between the substantially parallel planar conductors, wherein the magnetostrictive optical current sensor comprising an optical sensing element coupled to a magnetostrictive element, wherein the magnetostrictive element is configured to cause a strain in the optical sensing element in the presence of a magnetic field between the substantially parallel planar conductors, and wherein the optical sensing element is configured to receive an optical multifrequency interrogation signal and provide a wavelength modulated data signal indicative of magnitude of the current flowing through the conductors.

15. The power electronic assembly of claim 14, further comprising a dielectric element disposed between the substantially parallel planar conductors.

16. The power electronic assembly of claim 14, wherein the magnetostrictive optical sensor is embedded in the dielectric element.

17. The power electronic assembly of claim 14, wherein the optical sensing element comprises at least one sensing element selected from the group consisting of fiber Bragg gratings, fiber Fabry Perot cavities, optical microresonators, thin film filters, acousto-optic filters and combinations thereof.

18. The power electronic assembly of claim 10, wherein the power electronic device is at least one selected from the group consisting of transistors, insulated Gate Bipolar Transistors Metal Oxide Semiconductor Field Effect Transistors, diodes, resistors, capacitors, inductors and combinations thereof.

19. A method for estimating current in a power electronic device using a magnetostrictive optical sensor disposed between substantially parallel planar conductors electrically coupled to the power electronic device, the method comprising:
electrically powering the power electronic device by sending current through the substantially parallel conductors, wherein the current generates a magnetic field between the conductors and produces a strain in the magnetostrictive optical sensor;
interrogating the magnetostrictive optical sensor using a multifrequency interrogation signal, wherein the magnetostrictive optical sensor modulates the multifrequency interrogation signal to provide a wavelength modulated signal indicative of the current;
detecting the wavelength modulated signal; and
estimating a value of the current.

20. The method of claim 19, further comprising generating a reference signal.

21. The method of claim 20, wherein the wavelength modulated signal and the reference signal is used to generate difference frequency electrical signal.

22. The method of claim 21, further comprising measuring frequency of the difference frequency electrical signal.

23. The method of claim 21, wherein estimating the value of the current comprises determining the value of the current from the frequency of the difference frequency signal.
